(19) United States
(12) Patent Application Publication
(10) Pub. No.: US 2025/0003070 A1
(43) Pub. Date: Jan. 2, 2025

(54) SUBSTRATE-PROCESSING APPARATUS AND FILM-FORMING METHOD

(71) Applicant: Tokyo Electron Limited, Tokyo (JP)

(72) Inventors: Akira MATSUBARA, Iwate (JP); Fumiaki HAYASE, Iwate (JP); Muneyuki OTANI, Tokyo (JP)

(21) Appl. No.: 18/743,589

(22) Filed: Jun. 14, 2024

(30) Foreign Application Priority Data
Jun. 28, 2023 (JP) 2023-105898

(51) Int. Cl. C23C 16/455; C23C 16/458

(52) U.S. Cl. CPC C23C 16/45544; C23C 16/45512; C23C 16/45574; C23C 16/4584

(57) ABSTRACT

A substrate-processing apparatus includes a processing container, a raw material gas supply, a reaction gas supply, and a dehydration gas supply. The raw material gas supply is configured to supply an interior of the processing container with a raw material gas. The reaction gas supply is configured to supply the interior of the processing container with a reaction gas that reacts with the raw material gas. The dehydration gas supply is configured to supply the interior of the processing container with dehydration gas to eliminate moisture. The raw material gas is supplied to a substrate that is accommodated inside the processing container, followed by supplying the reaction gas and the dehydration gas to the substrate.

### CROSS-REFERENCE TO RELATED APPLICATIONS

This application is based upon and claims priority to Japanese Patent Application No. 2023-105898, filed on Jun. 28, 2023, the entire contents of which are incorporated herein by reference.

### BACKGROUND

### 1. Field of the Invention

The present disclosure relates to substrate-processing apparatuses and film-forming methods.

### 2. Description of the Related Art

For example, in Japanese Laid-Open Patent Publication No. 2020-21888, a substrate-processing apparatus is disclosed. In the disclosed substrate-processing apparatus, a raw material gas and a reaction gas (ozone gas) are supplied while rotating a rotary table on which substrates are mounted, thereby performing film formation on each of the substrates. In this type of the substrate-processing apparatus, after supplying a raw material gas to allow the raw material gas to be adsorbed on a substrate, moisture (H₂O) is generated through an oxidation reaction of a reaction gas in a step of supplying the reaction gas.

### SUMMARY

According to one aspect of the present disclosure, a substrate-processing apparatus includes a processing container, a raw material gas supply, a reaction gas supply, and a dehydration gas supply. The raw material gas supply is configured to supply an interior of the processing container with a raw material gas. The reaction gas supply is configured to supply the interior of the processing container with a reaction gas that reacts with the raw material gas. The dehydration gas supply is configured to supply the interior of the processing container with dehydration gas to eliminate moisture. The raw material gas is supplied to a substrate that is accommodated inside the processing container, followed by supplying the reaction gas and the dehydration gas to the substrate.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a cross-sectional view schematically illustrating an example of the substrate-processing apparatus of the present disclosure;

FIG. 2 is a plan view schematically illustrating an example of an inside of a processing container of the substrate-processing apparatus;

FIG. 3 is a cross-sectional partial view of the processing container in a range including a raw material gas nozzle, a dehydration gas nozzle, and a separation gas nozzle, concentrically taken along a rotary table;

FIG. 4 is an explanatory view illustrating an example of a behavior of molecules on a substrate in a reaction-gas-processing space;

FIG. 5 is an explanatory view illustrating an example of a behavior of molecules on the substrate in a second separation space and a raw-material-gas-processing space;

FIG. 6 is a flowchart illustrating an example of a film-forming method of the substrate-processing apparatus according to the present disclosure;

FIG. 7 is a table comparing a film thickness achieved by a film-forming process with supply of ethanol and a film thickness achieved by a film-forming process without supply of ethanol; and

FIG. 8 is a flowchart illustrating another example of the film-forming method according to the present disclosure.

### DETAILED DESCRIPTION

Hereinafter, non-limiting embodiments of the present disclosure will be described with reference to the attached drawings. Throughout the attached drawings, the same or corresponding members or parts are designated by the same or corresponding reference symbols, and redundant description thereof will be omitted.

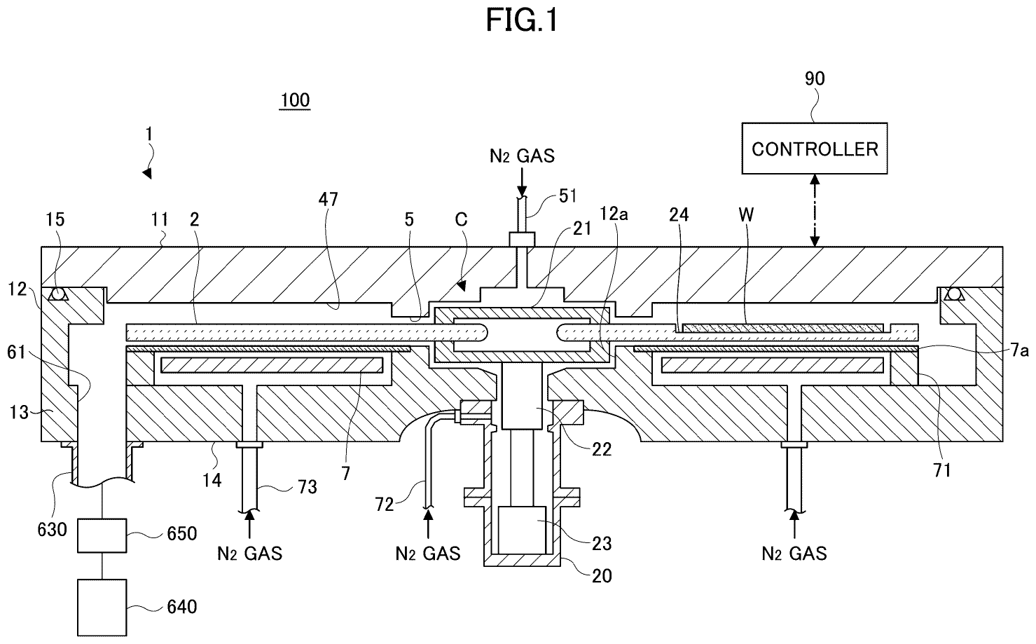

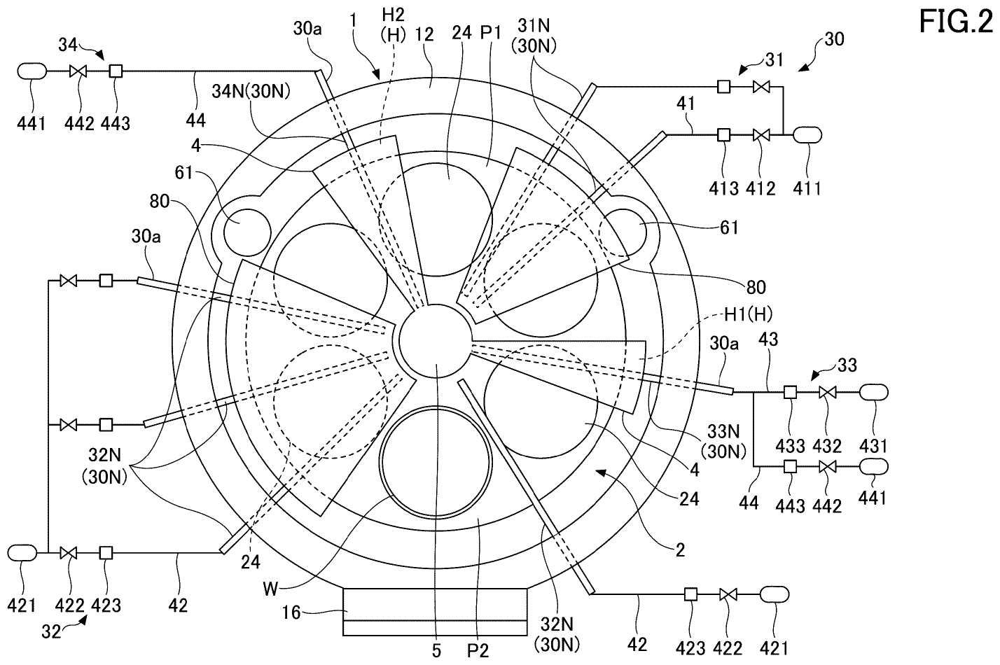

FIG. 1 is a cross-sectional view schematically illustrating an example of the substrate-processing apparatus 100 of the present disclosure. FIG. 2 is a plan view schematically illustrating an example of an inside of a processing container 1 of the substrate-processing apparatus 100. As illustrated in FIG. 1 and FIG. 2, the substrate-processing apparatus 100 of the present disclosure is a film-forming apparatus configured to form a film on a surface of a substrate W by atomic layer deposition (ALD) or molecular layer deposition (MLD). The substrate-processing apparatus 100 includes a processing container 1 and a rotary table 2. The processing container 1 accommodates therein a substrate W and is configured to perform a film-forming process on the substrate. The rotary table 2 is rotatably disposed in the processing container 1.

The processing container 1 has a flat cylindrical shape, and includes a processing chamber. The processing chamber accommodates therein a substrate W. For example, the processing container 1 is formed by assembling a container body 12 and a top plate 11. An upper part of the container body 12 is open, and the top plate 11 is disposed on the upper part of the container body 12. For the sake of convenience, illustration of the top plate 11 is omitted in FIG. 2. The container body 12 includes a bottom portion 14 and a side portion 13. The bottom portion 14 has a disc shape. The side portion 13 is projected upward from an outer edge of the bottom portion 14 in a vertical direction. The side portion 13 of the container body 12 and the top plate 11 are airtightly fastened together, for example, via a sealing member 15, such as an O-ring and the like.

The rotary table 2 has an annular shape, and an inner circumference of the rotary table 2 is fastened to a cylindrical core 21. The core 21 is fastened to an upper end of a rotary shaft 22 extending in a vertical direction. The rotary shaft 22 passes through the bottom portion 14 of the processing container 1, and a bottom end of the rotary shaft 22 is attached to a driver 23. The driver 23 is configured to rotate the rotary shaft 22 around an axis of the rotary shaft 22. Thus, the rotary table 2 is rotated around a center of the processing container 1 as a center of rotation via the rotary shaft 22 and the core 21.

The rotary shaft 22 and the driver 23 are accommodated in a case 20. The case 20 has a shape of a tube, and an upper part of the tube is open. A flange is provided at an upper end of the case 20 so that the case 20 is airtightly fastened to the bottom portion 14 of the processing container 1. Therefore, an inner space of the case 20 is shielded from the outside of the case 20, and communicates with the processing chamber of the processing container 1.

As illustrated in FIG. 2, a plurality (six in FIG. 2) of circular recesses 24 (mounting portions), on which substrates W may be respectively disposed, are formed in an upper surface of the rotary table 2 in a rotational direction of the rotary table 2. A substrate W to which a film-forming process is performed may be a semiconductor wafer of a silicon semiconductor, a compound semiconductor, an oxide semiconductor, or the like. The substrate W may have a pattern, such as a trench pattern, a via pattern, and the like.

The recess 24 has an inner diameter slightly larger than a diameter (e.g., 300 mm) of a substrate W and a depth substantially identical to a thickness of the substrate W. Thus, when a substrate W is mounted on the recess 24, an upper surface of the substrate W is at a substantially identical height to the upper surface (the region where the substrate W is not to be mounted) of the rotary table 2.

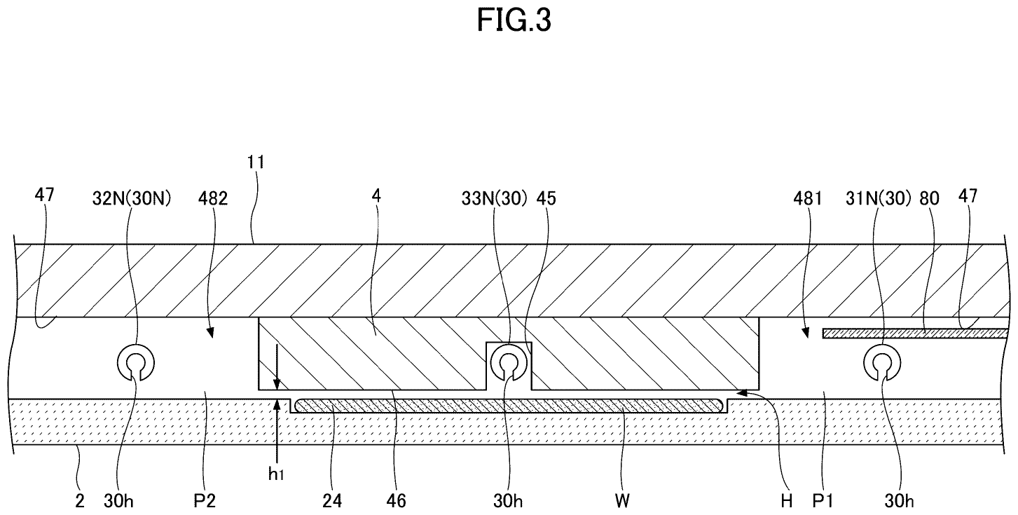

The substrate-processing apparatus 100 includes a gas supply 30 configured to supply an interior of the processing container 1 with a gas. For example, the gas supply 30 is composed of quartz, and includes nozzles 30N each linearly extending. An inlet port 30a that is a proximal end of each gas nozzle 30N is fastened to the side portion 13 of the processing container 1, and each gas nozzle 30N extends toward the vicinity of the center of the processing container 1 in the radius direction inside the processing container 1. Each gas nozzle 30N extends parallel to the upper surface of the rotary table 2 inside the processing container 1. Gas discharge holes 30h are formed in each gas nozzle 30N, and the gas discharge holes 30h are each open downward in a vertical direction toward the rotary table 2 (see also FIG. 3). The gas discharge holes 30h are aligned in an axial direction of each gas nozzle (a radius direction of the processing container 1) at identical intervals.

The gas supply 30 includes a raw material gas supply 31 configured to supply a raw material gas, a reaction gas supply 32 configured to supply a reaction gas, a dehydration gas supply 33 configured to supply a dehydration gas, and a separation gas supply 34 configured to supply a separation gas. Moreover, the raw material gas supply 31 includes two raw material gas nozzles 31N as the gas nozzle 30N. The reaction gas supply 32 includes four reaction gas nozzles 32N as the gas nozzle 30N. The dehydration gas supply 33 includes one dehydration gas nozzle 33N as the gas nozzle 30N. The separation gas supply 34 includes one separation gas nozzle 34N as the gas nozzle 30N. The processing container 1 of the illustrated example includes three reaction gas nozzles 32N, one separation gas nozzle 34N, two raw material gas nozzles 31N, one dehydration gas nozzle 33N, and one reaction gas nozzle 32N disposed in this order in the clockwise direction from the loading port 16 disposed at the side portion 13.

In the raw material gas supply 31, the inlet port 30a of each raw material gas nozzle 31N projecting toward the outside of the processing container 1 is coupled to a raw material gas supply path 41. In the raw material gas supply 31, a supply source 411 of the raw material gas, an open/close valve 412, and a flow rate controller 413 and the like are provided to the raw material gas supply path 41.

As the raw material gas supplied by the raw material gas supply 31, a gas including a metal element or semiconductor element may be appropriately selected. For example, the raw material gas is a gas for forming a High-k (high dielectric) film. Examples of the raw material gas include gases each including an organic metal or semiconductor including a metal element or semiconductor element. Examples of the metal element include aluminum (Al), zirconium (Zr), hafnium (Hf), and the like. Examples of the semiconductor element include silicon (Si) and the like. In the present embodiment, the raw material gas is a gas including zirconium. The raw material gas is preferably a gas that is adsorbed on a surface of the substrate W.

In the reaction gas supply 32, the inlet port 30a of each reaction gas nozzle 32N projected toward the outside of the processing container 1 is coupled to a reaction gas supply path 42. In the reaction gas supply 32, a supply source 421 of the reaction gas, an open/close valve 422, a flow rate controller 423, and the like are provided to the reaction gas supply path 42.

As the reaction gas supplied by the reaction gas supply 32, an oxidizing gas that reacts with the raw material gas adsorbed on the surface of the substrate W to generate an oxide is selected. In the present embodiment, the reaction gas is a gas including ozone (03) (e.g., a gas in which an ozone gas is mixed with an oxygen (O-) gas). Thus, the supply source 421 of the reaction gas may be an ozonizer.

In the dehydration gas supply 33, the inlet port 30a of the dehydration gas nozzle 33N projected toward the outside of the processing container 1 is coupled to a dehydration gas supply path 43. In the dehydration gas supply 33, a supply source 431 of the dehydration gas, an open/close valve 432, a flow rate controller 433, and the like are provided to the dehydration gas supply path 43.

As the dehydration gas, a gas that reacts with moisture (H—O) generated at the surface of the substrate W to eliminate the moisture is selected. In the present embodiment, the dehydration gas is an ethanol (EtOH) gas. A mechanism of elimination of the moisture with the dehydration gas will be described below. In addition to the dehydration gas supply path 43, a separation gas supply path 44 of the separation gas supply 34 is also coupled to the dehydration gas nozzle 33N. A supply source 441 of the separation gas, an open/close valve 442, a flow rate controller 443, and the like are provided to the separation gas supply path 44.

In the separation gas supply 34, the inlet port 30a of the separation gas nozzle 34N projected toward the outside of the processing container 1 is coupled to the separation gas supply path 44. In the separation gas supply 34, a supply source 441 of the separation gas, an open/close valve 442, a flow rate controller 443, and the like are provided to the separation gas supply path 44.

The separation gas supplied from the dehydration gas nozzle 33N or the separation gas nozzle 34N is appropriately selected from rare gases, such as argon (Ar), helium (He), and the like, and inert gases, such as a nitrogen (Ne) gas and the like. In the present embodiment, a nitrogen gas is used as the separation gas.

Moreover, the processing container 1 includes an activation plate 80 above the two raw material gas nozzles 31N, and another activation plate 80 above the three reaction gas nozzles 32N. Each activation plate 80 is formed into a box having a substantially fan shape as viewed in a plan view, and is configured to temporarily retain the supplied raw material gas or reaction gas. Thus, the activation plate 80 for the raw material gas nozzles 31N facilitates adsorption of the raw material gas. The activation plate 80 for the reaction gas nozzles 32N facilitates decomposition of the reaction gas (ozone gas) to activate the reaction gas. The activation plate 80 may be equipped with an activator, such as a catalyst, a laser, a heater, or the like.

Moreover, two projections 4 each ranging in the circumferential direction are disposed inside the processing container 1. Each projection 4 has a fan-like planar shape in which a tip of the fan is cut out into an arc shape. In the present embodiment, each projection 4 is arranged in a manner such that an inner arc of the projection 4 is linked to a protrusion 5 (described below) and an outer arc of the projection 4 is aligned with an inner circumferential surface of the side portion 13 of the processing container 1.

FIG. 3 is a cross-sectional partial view of the processing container 1 in the range including the raw material gas nozzle 31N, the dehydration gas nozzle 33N, and the separation gas nozzle 34N, where the cross-section is concentrically taken along the rotary table 2. As illustrated in FIG. 3, the projection 4 is mounted on a bottom surface of the top plate 11. Thus, a flat and low ceiling surface 46 and a ceiling surface 47 higher than the ceiling surface 46 are present in the processing container 1. The ceiling surface 46 is a bottom surface of the projection 4, and the ceiling surface 47 is positioned at both sides of the ceiling surface 46 in the circumferential direction.

In the projection 4, a groove 45 extending along a radius direction of the rotary table 2 is formed. The dehydration gas nozzle 33N is accommodated in the groove 45. A groove 45 is also similarly formed in the other projection 4, and the separation gas nozzle 34N is accommodated in the groove 45 (see FIG. 2).

In FIG. 3, the raw material gas nozzle 31N is disposed in the space 481 at the right side of the projection 4 (the space below the high ceiling surface 47 in the vertical direction). The reaction gas nozzle 32N is disposed in the space 482 at the left side of the projection 4 (the space below the high ceiling surface 47 in the vertical direction). The above-described gas nozzles 30N are disposed at the vicinity of the substrate W to be spaced apart from the ceiling surface 47. Note that, the above-described activation plate 80 is disposed between the raw material gas nozzle 31N and the ceiling surface 47.

The low ceiling surface 46 forms a separation space H, which is a narrow space, with the rotary table 2. A volume of the separation space H is smaller than a volume of the space 481 and a volume of the space 482. Thus, once a separation gas is supplied from the dehydration gas nozzle 33N, the separation gas causes a pressure of the separation space H to be higher than a pressure of the space 481 and a pressure of the space 482 so that the separation space H forms a pressure barrier between the space 481 and the space 482. Moreover, the separation gas flown from the separation space H into the spaces 481 and 482 functions as counterflows between the raw material gas and the reaction gas. Therefore, the raw material gas and the reaction gas are separated from each other by the separation space H so that the raw material gas and the reaction gas are inhibited from mixing and reacting with each other.

Referring back to FIG. 1 and FIG. 2, the protrusion 5 disposed at the bottom surface of the top plate 11 surrounds the outer periphery of the core 21 fastening the rotary table 2. The protrusion 5 is continued to the portion of the projection 4, which is at the side of the center of rotation. The protrusion 5 is configured so that a bottom surface of the protrusion 5 is at the same height to the ceiling surface 46.

Moreover, exhaust ports 61 are each provided between the rotary table 2 and the side portion 13 of the container body 12. To each exhaust port 61, an exhaust pipe 630 is coupled. The exhaust pipe 630 is coupled to a vacuum pump 640, which is a vacuum exhaust member, via a pressure controller 650.

A heater unit 7, which is a heater, is disposed in a space between the bottom portion 14 of the processing container 1 and the rotary table 2. The heater unit 7 is configured to heat a substrate W on the rotary table 2 at a target temperature (e.g., 300° C.) determined by a recipe. In order to inhibit entry of a gas into the space below the rotary table 2, an annular cover member 71 is disposed at the vicinity of and below the rim of the rotary table 2.

A part of the bottom portion 14, which is at the side of the center of rotation with respect to the space where the heater unit 7 is disposed, forms a protrusion 12a. The protrusion 12a is projected upward so that the protrusion 12a approaches the core 21 in the vicinity of the center of the bottom surface of the rotary table 2. A narrow space is formed between the protrusion 12a and the core 21. Moreover, a gap between an inner circumferential surface of a through hole, where the rotary shaft 22 is passed through the bottom portion 14, and the rotary shaft 22 is narrow. These narrow spaces are communicated to the case 20. A lid member 7a is disposed between the heater unit 7 and the rotary table 2. The lid member 7a covers a region between the cover member 71 and an upper edge of the protrusion 12a in the circumferential direction. For example, the lid member 7a is formed of quartz, and is configured to inhibit entry of a gas into the heater unit 7.

A purge gas supply pipe 72 is provided to the case 20. The purge gas supply pipe 72 is configured to supply a Ne gas, which is a purge gas (the same gas as the separation gas supplied by the separation gas nozzle 34N), into the narrow space. Moreover, purge gas supply pipes 73 are provided at the bottom portion 14 below the heater unit 7 at predetermined intervals in the circumferential direction. Each purge gas supply pipe 73 is configured to purge a space in which the heater unit 7 is disposed.

As a purge gas is supplied from the purge gas supply pipe 72, the supplied purge gas passes through the gap between the inner circumferential surface of the through hole for the rotary shaft 22 and the rotary shaft 22, and the gap between the protrusion 12a and the core 21, and the purge gas is then flown into the space between the rotary table 2 and the lid member 7a, followed by being discharged from the exhaust ports 61. As a purge gas is supplied from the purge gas supply pipe 73, the supplied purge gas is flown out from the space in which the heater unit 7 is accommodated, and the purge gas then passes through the gap (not illustrated) between the lid member 7a and the cover member 71, followed by being discharged from the exhaust ports 61. Owing to the above flows of the purge gas, mixing of the raw material gas and the reaction gas can be inhibited by the space below the center of the processing container 1 and the space below the rotary table 2.

Moreover, a separation gas supply pipe 51 is connected at the center of the top plate 11 of the processing container 1. The separation gas supply pipe 51 is configured to supply a separation gas (the same gas as the separation gas supplied by the separation gas nozzle 34N) into a space between the top plate 11 and the core 21. The separation gas supplied in this space is flown through the narrow space between the protrusion 5 and the rotary table 2 to travel along the surface of the rotary table 2. The space between the protrusion 5 and the rotary table 2 is maintained at a high pressure by the separation gas. Therefore, the raw material gas and the reaction gas are inhibited from passing through the center region C to be mixed with each other.

As illustrated in FIG. 2, the loading port 16 is formed at the side wall of the processing container 1. Through the loading port 16, a substrate W is passed between an external transfer arm (not illustrated) and the rotary table 2. The loading port 16 is opened and closed by a gate valve (not illustrated). A substrate W is passed between the rotary table 2 and the transfer arm when the recess 24 of the rotary table 2 is in the position facing the loading port 16. The recess 24 is a region on which a substrate is mounted. To this end, the substrate-processing apparatus 100 includes a lifting pin and a lifting mechanism (both not illustrated) in a position adjacent to the loading port 16 below the rotary table 2. The lifting pin passes through the recess 24 to lift the substrate W from the bottom surface of the substrate W.

Moreover, the substrate-processing apparatus 100 includes a controller 90 configured to control operations of a whole apparatus. The controller 90 is a computer including one or more processors, a memory, an input/output interface, and a communication interface. The one or more processors are one processor selected from a central processing unit (CPU), a graphic processing unit (GPU), an application specific integrated circuit (ASIC), a field-programmable gate array (FPGA), a circuit composed of multiple discrete semiconductors, etc., or any combination thereof. The one or more processors are configured to execute a program stored in the memory. The memory includes a main memory unit composed of a semiconductor memory or the like, and an auxiliary memory unit composed of a disk, a semiconductor memory (flash memory), or the like.

The above-described substrate-processing apparatus 100 supplies a raw material gas, a reaction gas, a dehydration gas, and a separation gas to the processing chamber of the processing container 1 under the control of the controller 90. Specifically, the dehydration gas nozzle 33N and the separation gas nozzle 34N supply a separation gas in the separation space H below the projection 4 so that the space inside the processing container 1 can be separated into a raw-material-gas-processing space P1, in which the raw material gas is supplied, and a reaction-gas-processing space P2, in which a reaction gas is supplied, as viewed in a plan view of the processing container 1.

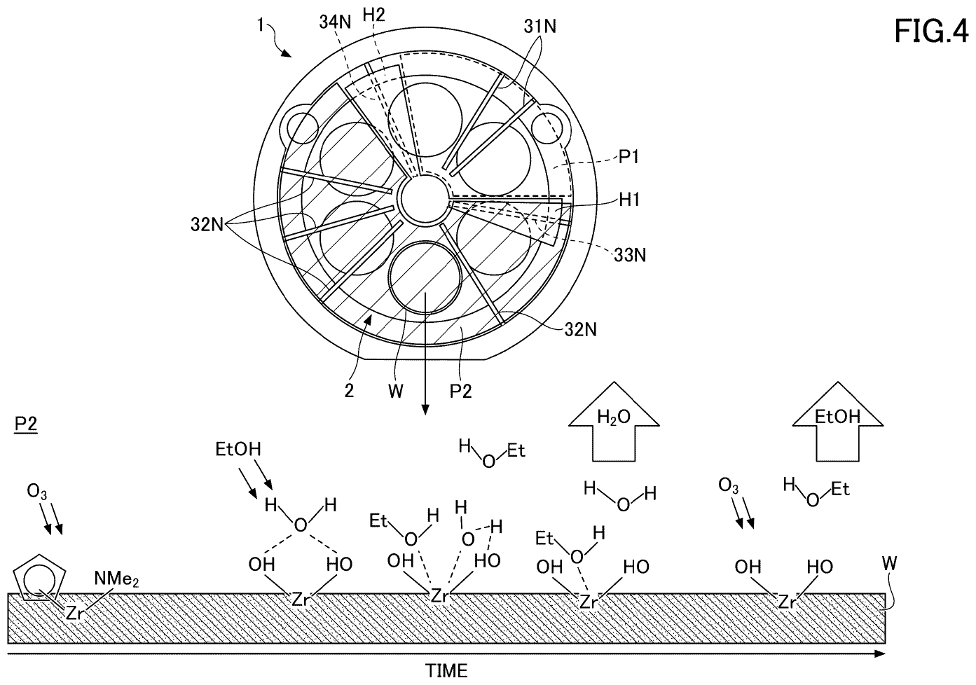

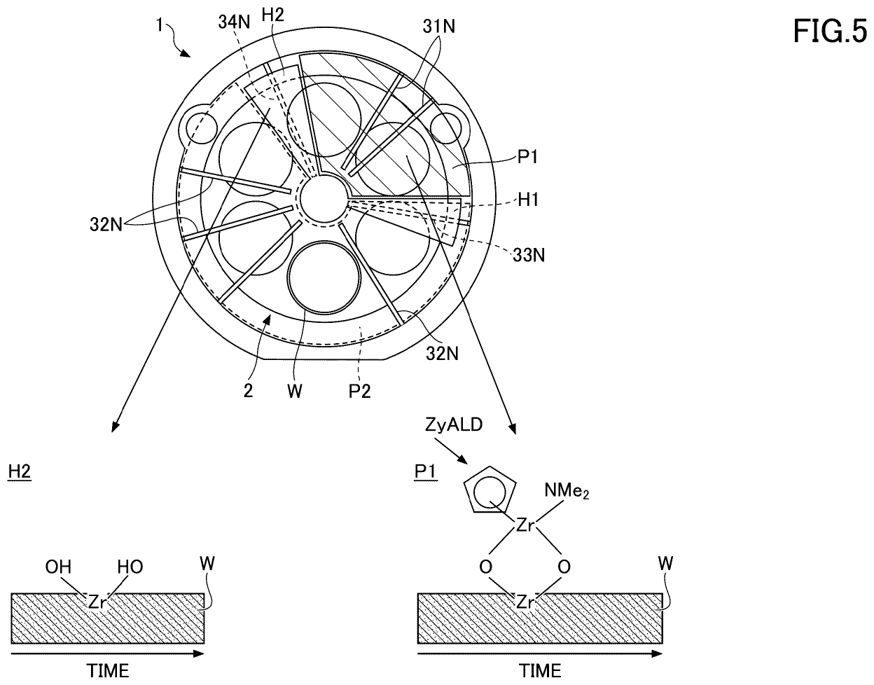

FIG. 4 is an explanatory view illustrating an example of a behavior of molecules on the substrate W in the reaction-gas-processing space P2. FIG. 5 is an explanatory view illustrating an example of a behavior of molecules on the substrate W in the second separation space H2 and the raw-material-gas-processing space P1. As illustrated in FIG. 4, the reaction-gas-processing space P2 corresponds to an arc-shaped region extending from a first separation space H1 by the projection 4 (the right side in FIG. 4), at which the dehydration gas nozzle 33N is disposed, to an area before reaching the projection 4 (the upper left side in FIG. 4), at which the separation gas nozzle 34N is disposed, in the clockwise direction. Specifically, the reaction-gas-processing space P2 is set as a region larger than the raw-material-gas-processing space P1. The reaction-gas-processing space P2 occupies a region extending from the approximate three o'clock direction to the approximate ten o'clock direction (½ or more of the processing chamber of the processing container 1), as viewed in a plan view of the processing container 1 of FIG. 4.

As illustrated in FIG. 5, the raw-material-gas-processing space P1 corresponds to an arc-shaped region extending between the second separation space H2 by the projection 4, at which the separation gas nozzle 34N is disposed, and the first separation space H1 by the projection 4, at which the dehydration gas nozzle 33N is disposed. The raw-material-gas-processing space P1 occupies a region extending from the approximate eleven o'clock direction to the approximate three o'clock direction, as viewed in a plan view of the processing container 1 of FIG. 4.

Next, the purpose of supplying a dehydration gas in addition to a raw material gas and a reaction gas in the substrate-processing apparatus 100 of the present disclosure will be described with reference to the bottom views of FIG. 4, and the bottom views of FIG. 5.

As illustrated in FIG. 4, at a beginning of the reaction-gas-processing space P2, a precursor including zirconium (Zr) (referred to as a zirconium precursor hereinafter) supplied as a raw material gas is adsorbed on a surface of the substrate W. Examples of the zirconium precursor include tetrakis(dimethylamino)zirconium, and tris(dimethylamino)cyclopentadienyl zirconium in which (NMe₂)₃ and cyclopentane are bonded to zirconium.

In the reaction-gas-processing space P2, an ozone (O₃) gas is discharged as a reaction gas from the reaction gas nozzle 32N to the zirconium precursor. The ozone gas causes ozone decomposition (ozone oxidation), which breaks carbon bonds within a molecule of the zirconium precursor. During the decomposition, moisture (H₂O), carbon dioxide (CO₂), nitrogen monoxide (NO), and the like are generated as reaction by-products in the reaction-gas-processing space P2. As a result of the ozone decomposition, the zirconium precursor is transformed into zirconium oxide to form a layer to which hydroxyl (OH) groups are bonded. Then, molecules of the moisture (H₂O) present in the reaction-gas-processing space P2 may be attracted to and adsorbed on the hydroxyl groups bonded to the zirconium through an excess reaction.

In the reaction-gas-processing space P2 of the present embodiment, an ethanol (EtOH) gas that is a dehydration gas is supplied from the dehydration gas nozzle 33N. The ethanol can dissociate the molecules of the moisture attached to the hydroxyl groups bonded to the zirconium, and the molecules of the moisture are replaced with molecules of the ethanol to be bonded to the zirconium. As a result, the moisture is detached (dehydrated) from the hydroxyl groups bonded to the zirconium. The moisture released from the above reaction is discharged from the exhaust port 61 together with other gases of the processing container 1 and reaction by-products.

At the surface of the zirconium oxide of the substrate W, the ethanol remains at the hydroxyl groups bonded to the zirconium. In the reaction-gas-processing space P2 of the present embodiment, an ozone gas is further supplied to the surface of the zirconium oxide layer to which the ethanol is deposited. As a result, the deposited ethanol is detached from the hydroxyl groups bonded to the zirconium. At the downstream side of the reaction-gas-processing space P2, a state where moisture or ethanol does not remain on the surface of the zirconium oxide is ultimately achieved.

Specifically, as illustrated in FIG. 5, only the zirconium oxide in the state where hydroxyl groups are bonded to the zirconium (from which moisture or ethanol is removed) is transported into the second separation space H2 by the projection 4 at which the separation gas nozzle 34N is disposed. Therefore, in the second separation space H2, the state where hydroxyl groups bonded to the zirconium are free from attachment or bonding with another substance is maintained, while a separation gas is discharged from the separation gas nozzle 34N.

Then, a zirconium precursor, which is a subsequent raw material gas, is discharged from the raw material gas nozzle 31N to the above zirconium oxide in the raw-material-gas-processing space P1. The zirconium precursor is bonded to form a covalent bond (Zr—O bond) with the zirconium having a hydroxyl group site, thereby easily bonding to the zirconium of the underlying layer to be stacked as an upper layer.

As described above, the substrate-processing apparatus 100 can suitably dehydrate the moisture deposited on the surface of the substrate W by supplying ethanol, which is a dehydration gas, so that a subsequent raw material gas can be smoothly stacked thereon. Specifically, the substrate-processing apparatus 100 can stably form a film of zirconium oxide, and can easily control to form the film at a target film thickness.

The substrate-processing apparatus 100 according to the present disclosure is basically configured as described above. Operations (film-forming method) and effects of the substrate-processing apparatus 100 of the present disclosure will be described hereinafter.

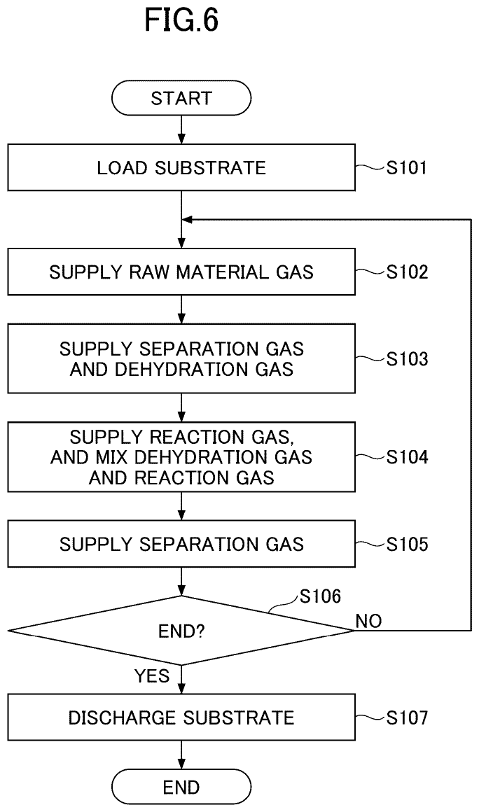

FIG. 6 is a flowchart illustrating an example of the film-forming method of the substrate-processing apparatus 100 of the present disclosure. The substrate-processing apparatus 100 executes steps S101 to S107 illustrated in FIG. 6 under the control of the controller 90. As described above, the substrate-processing apparatus 100 of the present disclosure supplies each of gases to a corresponding substrate W mounted on the rotary table 2 to perform a film-forming process, while rotating substrates W on the rotary table 2. Therefore, it can be also understood that the substrate-processing apparatus 100 can perform the steps S102 to S106 of FIG. 6 simultaneously. In this case, the processes of the steps S102 to S106 of FIG. 6 are sequentially executed on a corresponding substrate W due to the spatial segmentation during rotation of the rotary table 2.

Specifically, the controller 90 first opens the gate valve, and loads a substrate W through a loading port 16 (FIG. 3) with the transfer arm to mount the substrate W on a recess 24 of the rotary table 2 (step S101). During this process, the controller 90 intermittently rotates the rotary table 2 to mount a substrate W on each of the recesses 24. After loading all the substrates W, the controller 90 closes the gate valve to achieve airtightness of the processing container 1.

As a pre-processing of the film-forming process, the controller 90 discharges a separation gas from the dehydration gas nozzle 33N and the separation gas nozzle 34N, and exhausts the gas by the vacuum pump 640 and the pressure controller 650 to adjust the pressure of the entire processing chamber of the processing container 1 at a target pressure. During this process, the controller 90 may discharge a separation gas and a purge gas from the separation gas supply pipe 51 and the purge gas supply pipes 72 and 73. Subsequently, the controller 90 heats the substrates W at a target temperature by the heater unit 7, while rotating the rotary table 2 in the clockwise direction at a target rotational speed.

Once the pre-processing is completed, the controller 90 controls the gas supply 30 to supply an interior of the processing container 1 with a raw material gas, a reaction gas, a dehydration gas, and a separation gas. The raw material gas is separated from the reaction gas and the dehydration gas by separation spaces H in which two projections 4 are disposed (first separation space H1 and second separation space H2) so that mixing of the gases inside the processing container 1 is inhibited.

According to rotation of the rotary table 2, each substrate W goes through the steps S102 to S106 of FIG. 6 repeatedly. Specifically, at the step S102, as a substrate W passes through the raw-material-gas-processing space P1 by rotation of the rotary table 2, a raw material gas (zirconium precursor) supplied from the raw material gas nozzle 31N is adsorbed on a surface of the substrate W.

At the step S103, a dehydration gas (ethanol) and a separation gas are supplied from the dehydration gas nozzle 33N when the substrate W of the rotary table 2 passes through the first separation space H1 after the raw-material-gas-processing space P1. The first separation space H1 constitutes part of the reaction-gas-processing space P2. The dehydration gas supplied to the substrate W travels into the reaction-gas-processing space P2 in the rotational direction of the rotary table 2. Moreover, the separation gas discharged from the dehydration gas nozzle 33N is flowed into the raw-material-gas-processing space P1 and the reaction-gas-processing space P2 to separate the raw-material-gas-processing space P1 and the reaction-gas-processing space P2 from each other while increasing the pressure of the first separation space H1.

At the step S104, the substrate W of the rotary table 2 travels into the reaction-gas-processing space P2 after the first separation space H1. In the reaction-gas-processing space P2, a reaction gas (ozone gas) discharged from each of the reaction gas nozzles 32N and the previously supplied dehydration gas are mixed. As a result, the zirconium precursor adsorbed on the surface of the substrate W, the ozone, and the ethanol are reacted in the reaction-gas-processing space P2, as illustrated in FIG. 4. In the reaction-gas-processing space P2, the moisture at the vicinity of the surface of the substrate W is eliminated (dehydrated) by the dehydration gas, and the ethanol is removed by the reaction gas.

Specifically, three reaction gas nozzles 32N are disposed in the latter half of the reaction-gas-processing space P2 and are covered with the activation plate 80. Thus, even when ethanol is bonded to hydroxyl group sites of the zirconium on the substrate W, the ethanol can be effectively removed. Ultimately, the raw material gas adsorbed on the surface of the substrate W can be effectively oxidized in the reaction-gas-processing space P2 so that a thin film of a high quality oxide can be formed on the surface of the substrate W.

At the step S105, a separation gas is supplied from the separation gas nozzle 34N when the substrate W on the rotary table 2 passes through the second separation space H2 after the reaction-gas-processing space P2. The separation gas discharged from the separation gas nozzle 34N can blow off the moisture eliminated from the substrate W or the dehydration gas. Moreover, the separation gas is flowed into the raw-material-gas-processing space P1 and the reaction-gas-processing space P2 to separate the raw-material-gas-processing space P1 and the reaction-gas-processing space P2 from each other, while increasing the pressure of the second separation space H2.

At the step S106, the controller 90 determines whether or not the film-forming process is continued. When the film-forming process is continued (step S106: YES), the process is return to the step S102, and the sequential process flow is repeated as described above. Specifically, in the film-forming method, a cycle of the above steps S102 to S106 is repeated by continuously rotating the rotary table 2. As a result, a molecular layer of an oxide film is gradually deposited on the surface of the substrate W. For example, the controller 90 moreover monitors an execution duration of the film-forming process, and determines the end of the film-forming process, when the target execution duration is passed (step S106: NO).

Once the controller 90 determines the end of the film-forming process, the controller 90 terminates supply of each gas to the processing container 1 and rotation of the rotary table 2, and discharges the substrates W from the processing container 1 in the reverse order of the procedure by which the substrates W are loaded into the processing container 1 (step S107). As a result, the film-forming method is ended.

By performing the above film-forming method, the substrate-processing apparatus 100 can precisely (at a desired film thickness) form a film of zirconium oxide on a surface of a substrate W. Specifically, since the reaction gas and the dehydration gas are present in the reaction-gas-processing space P2, moisture deposited to the precursor adsorbed on the substrate W is eliminated. As a result, zirconium of the underlying layer and zirconium of an upper layer can be stably bonded to each other.

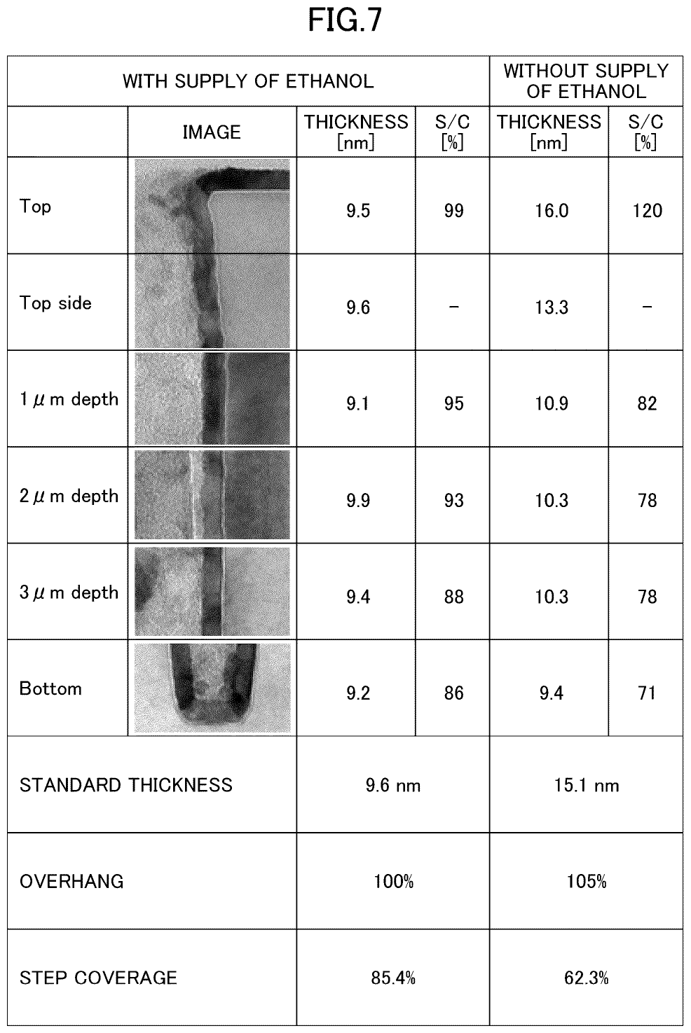

FIG. 7 is a table comparing a film thickness achieved by a film-forming process with supply of ethanol and a film thickness achieved by a film-forming process without supply of ethanol. Note that, the images in FIG. 7 are obtained by capturing an image of one trench formed in the substrate W. In each image, a gray portion is a wall of the substrate W constituting the trench, and a black portion is a film formed by the film-forming process.

Moreover, “Top,” “Top side,” “1 μm depth,” “2 μm depth,” “3μm depth,” and “Bottom” in FIG. 7 are assigned by segmenting the trench into sections from a top of the trench to a bottom of the trench, and “1 μm depth,” “2 μm depth,” “3 μm depth” each denote a depth from “Top.”

Moreover, “standard thickness” in FIG. 7 is a target value of a thickness of a film formed on the trench. “Overhang” is a ratio of a thickness of the film formed at the top of the trench to the standard thickness. “Step coverage” is a ratio of thickness of the film formed at the bottom of the trench to the standard thickness.

Comparing the film-forming process with the supply of ethanol and the film-forming process without the supply of ethanol in the table of FIG. 7, it can be demonstrated that both the overhang and the step coverage are improved with the supply of ethanol. Specifically, in the case where ethanol is not supplied, which is a comparative example, if the raw material gas adsorbed on the substrate W is oxidized with the reaction gas, moisture is generated during the oxidation reaction, and the generated moisture and the precursor adsorbed on the substrate W are excessively reacted. As a result, a film is excessively formed at the top of the trench. For example, the overhang in the case where ethanol is not supplied is 105%, indicating that the film is formed at the top of the trench at the greater thickness than the target thickness.

In the case where ethanol is supplied, conversely, the moisture generated during the oxidation of the adsorbed raw material gas is dehydrated so that an excess reaction with the precursor can be inhibited. For example, the overhang in the case where ethanol is supplied is 100% in FIG. 7, indicating that a target film thickness is achieved.

The step coverage in the case where ethanol is not supplied is 62.3%. Specifically, an excess reaction due to the moisture tends to occur at the top of the trench, and the film is not sufficiently formed at the bottom of the trench. Conversely, the step coverage in the case where ethanol is supplied is 85.4%. This indicates that a film is sufficiently formed at the bottom of the trench by dehydrating the moisture with ethanol.

As described above, in the substrate-processing apparatus 100 and film-forming method according to the present disclosure, a thickness of a film formed on a trench can be more conformal by supplying ethanol serving as a dehydration gas so that a quality of the film is improved.

Note that, the substrate-processing apparatus 100 and film-forming method according to the present disclosure are not limited to the above embodiments, and various modifications may be made. For example, the dehydration gas supply 33 (dehydration gas nozzle 33N) for supplying a dehydration gas to the processing container is not limited to be disposed in the first separation space H1, and may be disposed in any section of the reaction-gas-processing space P2. As one example, the dehydration gas nozzle 33N may be disposed in a position between one or more reaction gas nozzles 32N and another one or more reaction gas nozzles 32N in the reaction-gas-processing space P2. Alternatively, the dehydration gas nozzle 33N may be disposed at the downstream side (the rear side in the rotational direction) of all of one or more reaction gas nozzles 32N. In this case, the dehydration gas remaining in the reaction-gas-processing space P2 can be eliminated by the reaction gas.

Moreover, the substrate-processing apparatus 100 according to the present disclosure is configured to rotate (revolve) substrates W by the rotary table 2, but the configuration thereof is not limited to the above. For example, the substrate-processing apparatus may be configured to rotate (revolve) each mounting portion for supporting the substrate W in the rotary table 2.

Moreover, the substrate-processing apparatus 100 is not limited to the configuration in which the rotary table 2 is disposed inside the processing container 1 to process multiple substrates W. For example, the substrate-processing apparatus 100 may be configured as a single wafer processing apparatus where one substrate W is transported into the processing container and the film-forming process is performed on the one substrate W by sequentially supplying a raw material gas, a reaction gas, and a dehydration gas. Alternatively, the substrate-processing apparatus 100 may be configured as a batch processing apparatus where multiple substrates W are aligned in a longitudinal direction or a lateral direction accommodated in the processing container, and the film-forming process is performed on the multiple substrates W by sequentially supplying a raw material gas, a reaction gas, and a dehydration gas.

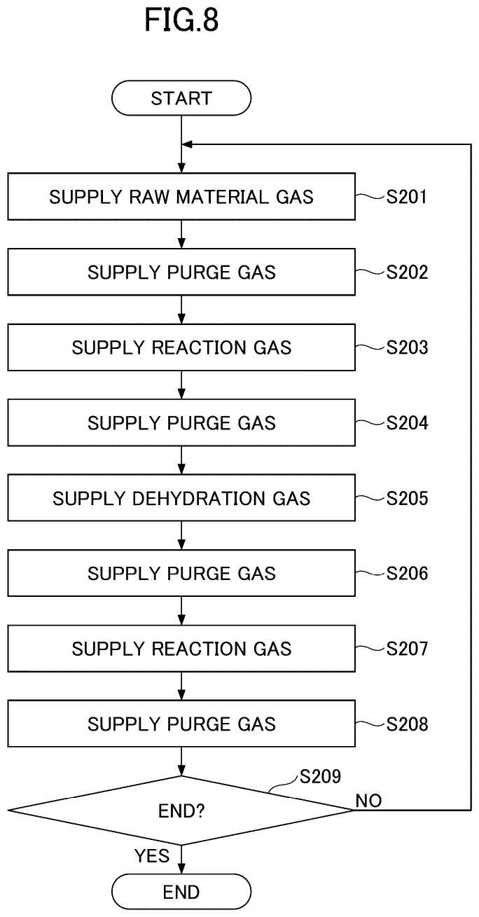

In the single wafer processing or batch processing substrate-processing apparatus, a gas-supplied state identical to the above substrate-processing apparatus 100 is created according to the timings of supplying the interior of the processing container with gases. For example, FIG. 8 is a flowchart illustrating one example of the film-forming method in which the timings of supplying gases are differentiated from one another.

The single wafer processing or batch processing substrate-processing apparatus supplies various gases according to the process flow illustrated in FIG. 8. First, the substrate-processing apparatus performs a step of supplying a raw material gas (zirconium precursor) to a processing container in which one or more substrates W are accommodated (step S201). As the step of supplying the raw material gas is performed for a set period (e.g., 15 seconds), the substrate-processing apparatus subsequently performs a step of supplying a purge gas (inert gas, such as No) to exhaust the raw material gas remaining in the processing container (step S202).

As the step of supplying the purge gas is performed for a set period (e.g., 15 seconds), the substrate-processing apparatus subsequently performs a step of supplying a reaction gas (ozone gas) (step S203). Thus, the raw material gas adsorbed on the substrate W can be oxidized with the reaction gas. As the step of supplying the reaction gas is performed at a set period (e.g., 30 seconds), the substrate-processing apparatus subsequently performs a step of supplying a purge gas (step S204).

As the step of supplying the purge gas is performed for a set period (e.g., 15 seconds), the substrate-processing apparatus subsequently performs a step of supplying a dehydration gas (ethanol gas) (step S205). Thus, the moisture attached to the surface of the substrate W can be dehydrated by the dehydration gas. As the step of supplying the dehydration gas is performed for a set period (e.g., 15 seconds), the substrate-processing apparatus subsequently performs a step of supplying a purge gas (step S206).

As the step of supplying the purge gas is performed for a set period (e.g., 5 seconds), the substrate-processing apparatus subsequently performs a step of supplying a reaction gas (ozone gas) again (step S207). Thus, the dehydration gas deposited on the surface of the substrate W can be eliminated by the reaction gas. As the step of supplying the reaction gas is performed for a set period (e.g., 5 seconds), the substrate-processing apparatus sequentially performs a step of supplying a purge gas (step S208). As the step of supplying the purge gas for a set period (e.g., 5 seconds), one cycle of the film-forming process is ended.

At the step S209, the substrate-processing apparatus determines whether or not the film-forming process is continued. When the film-forming process is continued, the process is returned to the step S201, and the sequential process flow is repeated as described above. According to the above film-forming method, the single wafer processing or batch processing substrate-processing apparatus can precisely control a thickness of a film formed on a surface of a substrate W.

The technical concepts and effects of the present disclosure described in the above embodiments will be described hereinafter.

The substrate-processing apparatus 100 according to the first embodiment of the present disclosure includes a processing container 1, a raw material gas supply 31 configured to supply an interior of the processing container 1 with a raw material gas, a reaction gas supply 32 configured to supply the interior of the processing container 1 with a raw material gas, and a dehydration gas supply 33 configured to supply the interior of the processing container 1 with a dehydration gas to eliminate moisture. The raw material gas is supplied to a substrate W that is accommodated inside the processing container 1, followed by supplying the reaction gas and the dehydration gas to the substrate W.

According to the above, the substrate-processing apparatus 100 supplies the reaction gas and the dehydration gas in the film-forming process so that a film can be precisely formed on the substrate W. For example, the substrate-processing apparatus 100 can achieve film formation with a conformal film thickness on a substrate W having projections or recesses, such as trenches, by supplying the reaction gas and the dehydration gas.

Moreover, the processing container 1 includes a space (reaction-gas-processing space P2) in which the reaction gas supplied by the reaction gas supply 32 and the dehydration gas supplied by the dehydration gas supply 33 are mixed. Thus, in the space of the processing container 1 where the dehydration gas and the reaction gas are mixed, a reaction between the reaction gas and the raw material gas, and dehydration by the dehydration gas are facilitated at a surface of the substrate W.

Moreover, in the processing container 1, at least the reaction gas is supplied to the substrate W after supplying the dehydration gas to the substrate W. Thus, the substrate-processing apparatus 100 can eliminate the excess dehydration gas using the reaction gas so that a reduction in a film thickness due to the residual dehydration gas can be inhibited.

Moreover, the interior of the processing container 1 is supplied with a separation gas. The separation gas separates the supplied raw material gas from the supplied reaction gas and dehydration gas in terms of a space or a time. Thus, the substrate-processing apparatus 100 can reduce a deposition of a reaction product between the raw material gas and the reaction gas on a member, such as an inner surface of the processing container 1, and the like.

Moreover, the substrate-processing apparatus 100 further includes a rotary table 2 rotatably disposed in the processing container 1. The rotary table 2 includes mounting portions (recesses 24) in which the substrate W is mounted. Each of the mounting portions (recesses 24) is disposed in a position set apart from a center of rotation. The raw material gas supply 31 includes a raw material gas nozzle 31N configured to discharge the raw material gas in a direction crossing a rotational direction of the rotary table 2 toward the mounting portions. The reaction gas supply 32 includes a reaction gas nozzle 32N configured to discharge the reaction gas in a direction crossing the rotational direction of the rotary table 2 toward the mounting portions. The dehydration gas supply 33 includes a dehydration gas nozzle 33N configured to discharge the dehydration gas in a direction crossing the rotational direction of the rotary table 2 toward the mounting portions. Thus, the substrate-processing apparatus 100 can precisely perform the film-forming process on the multiple substrates W mounted on the rotary table 2.

Moreover, the dehydration gas nozzle 33N is configured to supply a separation gas together with the dehydration gas. The separation gas separates the raw material gas discharged from the raw material gas nozzle 31N from the reaction gas discharged from the reaction gas nozzle 32N. Thus, the substrate-processing apparatus 100 can stably supply the dehydration gas to a surface of the substrate W, as well as separating the raw material gas and the reaction gas with the separation gas.

Moreover, the dehydration gas nozzle 33N is disposed in a space (first separation space H1) enabling to create a higher pressure than a pressure of a space (raw-material-gas-processing space P1) in which the raw material gas is discharged and a pressure of a space (reaction-gas-processing space P2) in which the reaction gas is discharged inside the processing container 1. Thus, the substrate-processing apparatus 100 can more assuredly separate the space of the raw material gas from the space of the reaction gas inside the processing container 1.

Moreover, the raw material gas is a gas including a metal that is zirconium, hafnium, aluminum, or silicon. Thus, the substrate-processing apparatus 100 can suitably form a film of the above raw material on a surface of the substrate W.

Moreover, the reaction gas is a gas including ozone. Thus, the substrate-processing apparatus 100 can facilitate oxidation of the raw material gas adsorbed on the surface of the substrate W.

Moreover, the dehydration gas is a gas including ethanol. Thus, the substrate-processing apparatus 100 can stably dehydrate the moisture generated by the reaction between the raw material gas and the reaction gas.

Moreover, the film-forming method according to the second embodiment of the present disclosure includes supplying an interior of the processing container 1 in which a substrate W is accommodated with a raw material gas, and after the supplying with the raw material gas, supplying the interior of the processing container in which the substrate W is accommodated with a reaction gas and a dehydration gas. The reaction gas reacts with the raw material gas. The dehydration gas eliminates moisture. In this case, the film-forming method can precisely form a film on the substrate W.

The substrate-processing apparatus 100 and film-forming method according to the embodiments disclosed herein are illustrative in all respects and not restrictive. The embodiments can be modified and improved in various forms without departing from the scope and spirit of the present disclosure. The features described in the above embodiments may have other configurations and can be combined within a range that does not cause any inconsistency.

As has been described above, the present disclosure can provide a technique of highly precisely forming a film on a substrate.

What is claimed is:

1. A substrate-processing apparatus, comprising:
a processing container;
a raw material gas supply configured to supply an interior of the processing container with a raw material gas;
a reaction gas supply configured to supply the interior of the processing container with a reaction gas, the reaction gas reacting with the raw material gas; and
a dehydration gas supply configured to supply the interior of the processing container with dehydration gas to eliminate moisture, wherein
the raw material gas is supplied to a substrate that is accommodated inside the processing container, followed by supplying the reaction gas and the dehydration gas to the substrate.

2. The substrate-processing apparatus according to claim 1, wherein the processing container includes a space in which the reaction gas supplied by the reaction gas supply and the dehydration gas supplied by the dehydration gas supply are mixed.

3. The substrate-processing apparatus according to claim 2, wherein, in the processing container, at least the reaction gas is supplied to the substrate after supplying the dehydration gas to the substrate.

4. The substrate-processing apparatus according to claim 2, wherein the interior of the processing container is supplied with a separation gas, the separation gas separating the supplied raw material gas from the supplied reaction gas and the supplied dehydration gas in terms of a space or a time.

5. The substrate-processing apparatus according to claim 1, further comprising:
a rotary table rotatably disposed in the processing container, the rotary table including mounting portions in each of which the substrate is mounted, each of the mounting portions being disposed in a position set apart from a center of rotation, wherein
the raw material gas supply includes a raw material gas nozzle configured to discharge the raw material gas in a direction crossing a rotational direction of the rotary table toward the mounting portions,
the reaction gas supply includes a reaction gas nozzle configured to discharge the raw material gas in a direction crossing the rotational direction of the rotary table toward the mounting portions, and
the dehydration gas supply includes a dehydration gas nozzle configured to discharge the dehydration gas in a direction crossing the rotational direction of the rotary table toward the mounting portions.

6. The substrate-processing apparatus according to claim 5, wherein the dehydration gas nozzle is configured to supply a separation gas together with the dehydration gas, the separation gas separating the raw material gas discharged from the raw material gas nozzle from the reaction gas discharged from the reaction gas nozzle.

7. The substrate-processing apparatus according to claim 6, wherein the dehydration gas nozzle is disposed in a space enabling to create a higher pressure than a pressure of a space into which the raw material gas is discharged and a pressure of a space into which the reaction gas is discharged inside the processing container.

8. The substrate-processing apparatus according to claim 1, wherein the raw material gas is a gas including zirconium, hafnium, aluminum, or silicon.

9. The substrate-processing apparatus according to claim 1, wherein the reaction gas is a gas including ozone.

10. The substrate-processing apparatus according to claim 1, wherein the dehydration gas is a gas including ethanol.

11. A film-forming method, comprising:
supplying an interior of a processing container, in which a substrate is accommodated, with a raw material gas; and
after the supplying with the raw material gas, supplying the interior of the processing container with a reaction gas and a dehydration gas, the reaction gas reacting with the raw material gas, and the dehydration gas eliminating moisture.
